(19) United States
(12) Patent Application Publication
(10) Pub. No.: US 2005/0210012 A1
(43) Pub. Date: Sep. 22, 2005

(54) Method for managing website group

(75) Inventors: Lien-Chun Ding, Taoyuan (TW); Ching-Kang Lee, Taipei (TW)

Correspondence Address: BEVER HOFFMAN & HARMS, LLP;TRI-VALLEY OFFICE, 1432 CONCANNON BLVD., BLDG. G, LIVERMORE, CA, 94550, US

(73) Assignee: EC-Server com., INC., Taipei (TW)

(21) Appl. No.: 10/969,163

(22) Filed: Oct. 19, 2004

(30) Foreign Application Priority Data
Mar. 16, 2004 (TW) 093107014

(51) Int. Cl. G06F 17/30; G11C 5/00; G06F 15/16

(52) U.S. Cl. 707/3; 707/206; 707/200; 711/1; 709/203

(57) ABSTRACT

A method for managing a website group is provided. The website group includes a main website and at least one sub-website. The method includes steps of (a) providing a database, (b) configuring a data storage area for being accessed by the main website and the sub-website, (c) sharing a first message shown on the main website the with sub-website via the data storage area, and determining whether the first message is shown on the sub-website, and (d) sharing a second message shown on the sub-website with the main website via the data storage area, and determining whether the second message is shown on the main website.

### FIELD OF THE INVENTION

The present invention is related to a method for managing a website group, and more particularly to a method for managing the website group including a main website and at least one sub-website.

### BACKGROUND OF THE INVENTION

It is a general situation that a network is used as a medium for querying and acquiring specific data and general information due to the popularization of Internet.

In early days, websites of different companies of the same industry or business are usually independent. When the newest information from the respective companies of a certain industry or business in a certain area is designed to be acquired or the newest developing trend data is designed to be inquired, a search engine would be necessary used for acquiring or inquiring the designed information or data. However, these data items retrieved from the search engine belong an unsorted and disarranged mass thereof, so that the designed data items would be determined one by one through the manpower and this process for retrieving information or data would be very difficult.

Moreover, if a main website of the industry or of the business association for the member service thereof is provided, the data source of the main website will be published after collecting data item by item, logining into the various member sub-websites and editing the relevant data thereof. Further, if the members of the industry or business association want to update or announce the newest information or the commodity data on the main website, they need to provide the main website administrator in the industry or business association with the acquired data or information by the traditional method, such as telephone, email or general mail, first. Then, the main website administrator in the industry or business association could update or publish the relevant data or information accordingly, the relevant process in shown in FIG. 1. Since the conventional procedure for transferring information or data is not only time-consuming but also inefficiency, the manpower resource is wasted at the same time.

Please refer to FIGS. 2(a) to 2(d), which are web pages showing the searching relationships between the main websites and the sub-websites according to the prior art. As shown in FIG. 2(a), if a user wants to search an industry or business with respect to the finance bills in Taiwan, a key phrase “bills finance association” would be inputted to a search engine, such as Google, to acquire the desired data or information. In FIG. 2(a), it is found that 936,000 likelihood searching results are retrieved from the search engine and five searching results just are shown therein. Further, the first searching result “Taipei Bills Finance Association” in the searching list would be determined to be the desired main website and a hyperlink to the home page of the main website for Taipei Bills Finance Association would be performed by clicking the relevant item, as shown in FIG. 2(b).

Moreover, as shown in FIG. 2(b), a hyperlink option “member corporations” is listed on the left of the web page of the main website, and a web page listing all sub-website hyperlinks with the bills finance industries in Taiwan, such as International Bills Finance Corporation, as shown in FIG. 2(c), would be show out after clicking the relevant hyperlink option.

According to the hyperlinks of sub-websites shown in FIG. 2(c), a specific sub-website hyperlink option such as that for a website hyperlink to International Bills Finance Corporation is clicked and then a web page of the sub-website, i.e. a home page of the website of International Bills Finance Corporation, would come out, as shown in FIG. 2(d).

Please refer to FIG. 2(d), which is a web page showing the home page of the website of International Bills Finance Corporation. Some newest information, such as financial statements, headlines or new business illustrations are often updated and published by a designated administrator of the website of International Bills Finance Corporation. Further, if it is desirous to update or publish the newest information from the website of International Bills Finance Corporation, i.e. the sub-website, on the website of Taipei Bills Finance Association, i.e. the main website, the designated administrator needs to provide a main website administrator of Taipei Bills Finance Association with the newest information, first. Then, the newest information would be updated or published to the website of Taipei Bills Finance Association by the main website administrator. That is to say, the main website and the sub-website merely include a simple connection relationship therebetween even though the website of Taipei Bills Finance Association, i.e. the main website, has a hyperlink to the website of International Bills Finance Corporation, i.e. the sub-website. Therefore, updated or published the website information in the main website and the sub-websites remain respectively independent and include no concern with the another, so that the synchronous updating and transferring of the relevant information on the main website and the sub-websites could be performed only by the manual operation.

Therefore, a purpose of the present invention is to develop a process to deal with the above situations encountered in the prior art.

### SUMMARY OF THE INVENTION

It is therefore an object of the present invention to provide a method for managing a website group including a simple and fast procedure for performing the synchronization of the message transmission between the main websites and the sub-website without losing the independent feature of the sub-website.

According to an aspect of the present invention, a method for managing a website group is provided. The website group includes a main website and at least one sub-website. The method includes steps of (a) providing a database, (b) configuring a data storage area for being accessed by the main website and the sub-website, (c) sharing a first message shown on the main website the with sub-website via the data storage area, and determining whether the first message is shown on the sub-website, and (d) sharing a second message shown on the sub-website with the main website via the data storage area, and determining whether the second message is shown on the main website.

Preferably, the data storage area is in the database.

Preferably, the main website and the sub-website include independent domain names, respectively.

Preferably, data storage area is accessed by an additional sub-website added in the website group.

Preferably, the sub-website includes a first data classification, a first data attribute and a URL address for being respectively retrieved by the main website.

Preferably, the step (c) further includes a step of (c1) determining by the main website whether the first message is shared with the sub-website.

Preferably, the step (d) further includes a step of (d1) determining by the sub-website whether the second message is shared with the main website.

Preferably, the sub-website includes a second data classification and a second data attribute corresponding to the first message, and the second data classification and the second data attribute shown on the sub-website are determined by one of the main website and the sub-website.

Preferably, the main website includes a data classification and a data attribute corresponding to the second message, and the data classification and the data attribute shown on the main website are determined by one of the main website and the sub-website.

According to another aspect of the present invention, a method for managing a website group is provided. The website group includes a main website and at least one sub-website. The method includes steps of (a) providing a database, (b) configuring a data storage area in the database for being accessed by the main website and the sub-website, and (c) sharing a first message shown on the main website with the sub-website via the data storage area, and determining whether the first message is shown on the sub-website.

Preferably, the method further includes a step of (d) sharing a second message shown on the sub-website with the main website via the data storage area, and determining whether the second message is shown on the main website.

Preferably, the step (c) further includes a step of (c1) determining by the main website whether the first message is shared with the sub-website.

According to another aspect of the present invention, a method for managing a website group is provided. The website group includes a main website and at least one sub-website. The method includes steps of (a) providing a database, (b) configuring a data storage area in the database for being accessed by the main website and the sub-website, and (c) sharing a first message shown on the sub-website with the main website via the data storage area, and determining whether the first message is shown on the main website.

Preferably, the method further includes a step of (d) sharing a second message shown on the main website with the sub-website via the data storage area, and determining whether the second message is shown on the sub-website

Preferably, the step (c) further includes a step of (c1) determining by the sub-website whether the second message is shared with the main website.

The above contents and advantages of the present invention will become more readily apparent to those ordinarily skilled in the art after reviewing the following detailed descriptions and accompanying drawings, in which:

### BRIEF DESCRIPTION OF THE DRAWINGS

FIG. 1 is a flow chart showing the data processing between the main website and the sub-website according to the prior art;

FIGS. 2(a) to 2(d) are the web pages respectively showing the searching relationships between the main websites and the sub-websites according to the prior art;

FIG. 3 is a flow chart showing a method for managing a website group according to a preferred embodiment of the present invention; and

FIGS. 4(a) to 4(e) are the web pages respectively showing the relationships between the main websites and the sub-websites according to the preferred embodiment of the present invention.

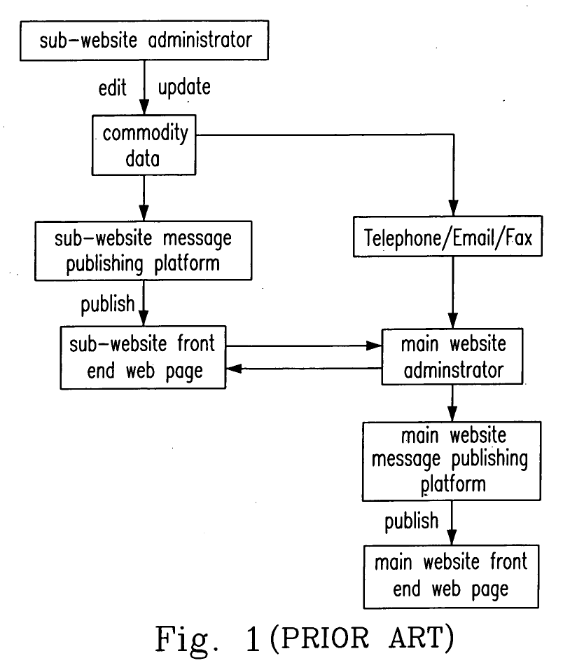

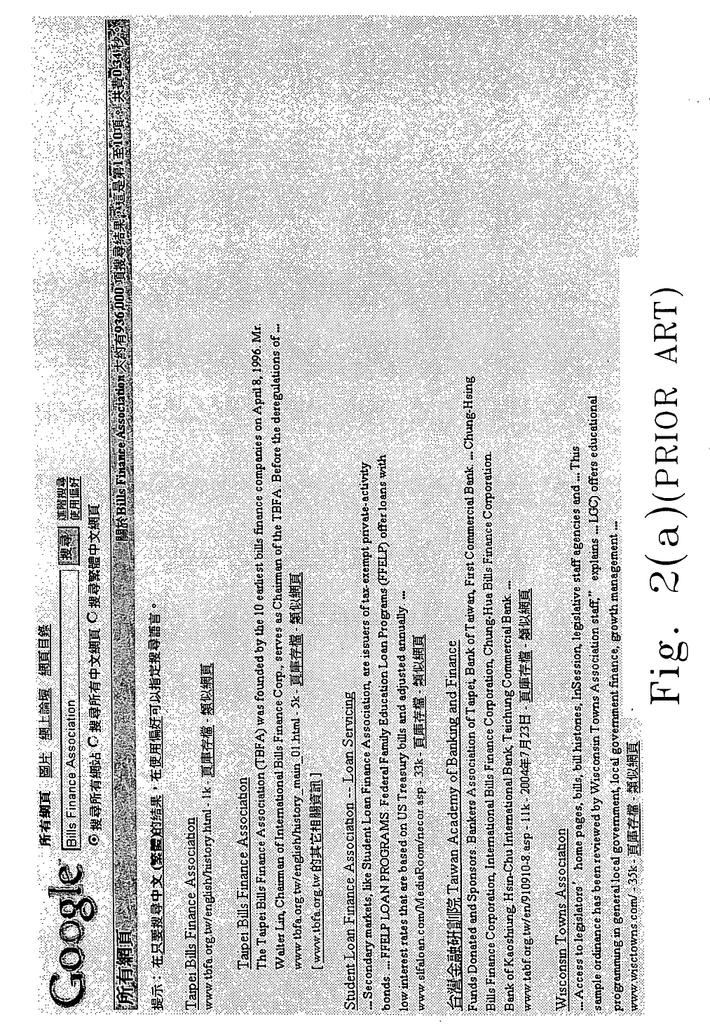

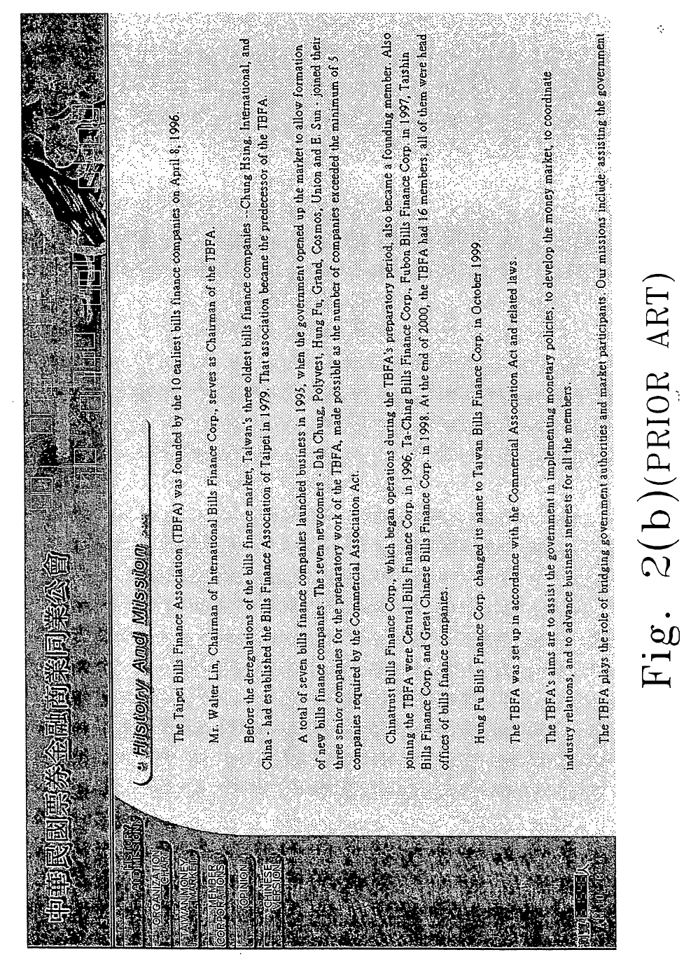

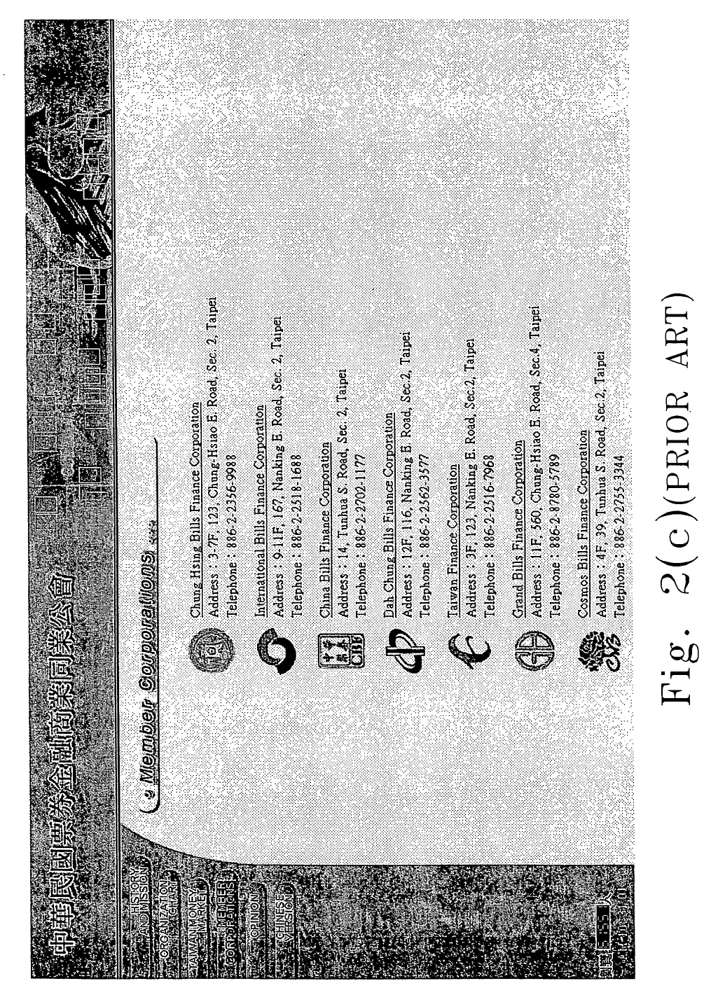

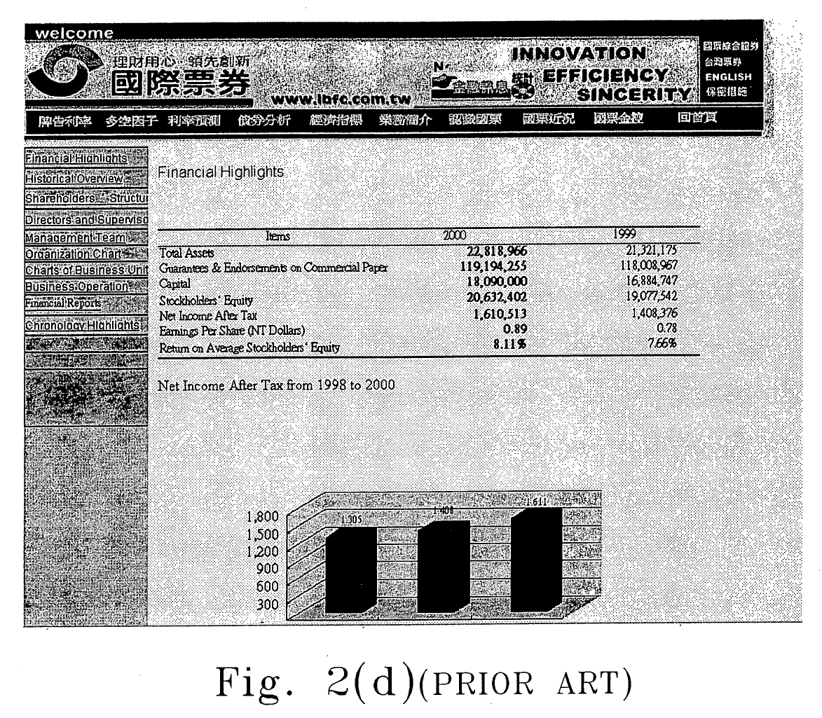

### DETAILED DESCRIPTION OF THE PREFERRED EMBODIMENTS

The present invention will now be described more specifically with reference to the following embodiment. It is to be noted that the following descriptions of preferred embodiment of this invention are presented herein for purpose of illustration and description only; it is not intended to be exhaustive or to be limited to the precise form disclosed.

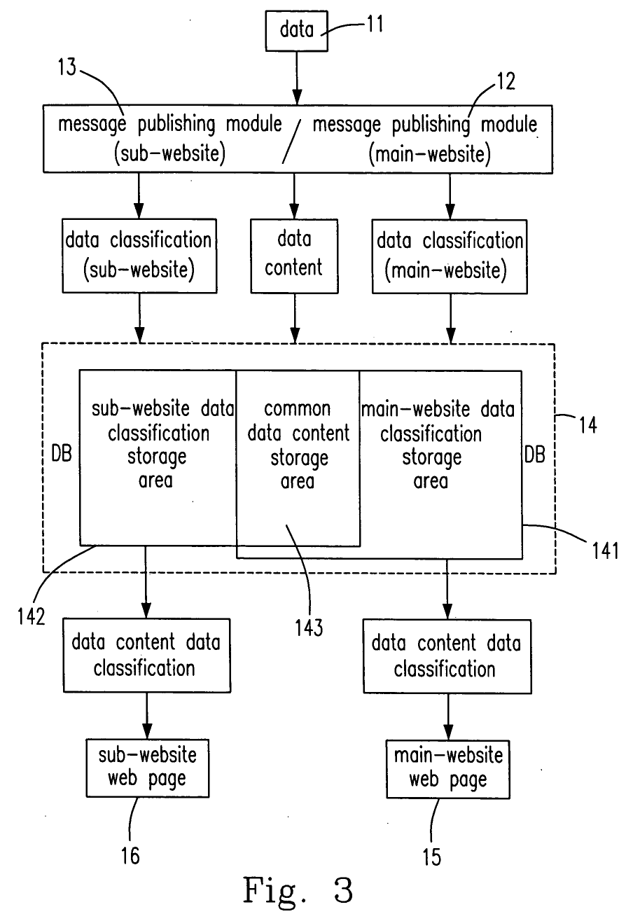

Please refer to FIG. 3, which is a flow chart showing a method for managing a website group according to a preferred embodiment of the present invention, wherein the website group includes a main website and at least one sub-website. The present method is applied between a main website message publishing module 12 and at least one sub-website message publishing module 13, and is used for configuring data 11 in the three aspects as following:
(1) The data classification for data 11 in a sub-website;
(2) The content of data 11; and
(3) The data classification for data 11 in a main website.

Please refer to FIG. 3, a database (DB) 14 is provided to configure a common data content storage area 143 for simultaneously being accessed by a main website data classification storage area 141 and a sub-website data classification storage area 142.

In other words, both the main website data classification storage area 141 and the sub-website data classification storage area 142 include the common data content storage area 143. While the data 11 is updated in the main website, the data content of the data 11 and the data classification thereof in the main website are respectively stored in the common data content storage area 143 and the main website data classification storage area 141 by the main website message publishing module 12. Then, the data 11 would be published in the main website web page 15. Furthermore, the data 11 would be shared with the sub-website data classification storage area 142 via the common data content storage area 143 and whether the data 11 is shown on the sub-website web page 16 is determined by the sub-website message publishing module 13. Further, whether the data 11 updated in the main website shared with the sub-website message publishing module 13 or not is determined by the main website message publishing module 12 and then whether the data 11 is shared with the sub-website data classification storage area 142 via the common data content storage area 143 or not is determined by the main website data classification storage area 141.

Besides, if the data 11 is updated in the sub-website, the data content of the data 11 and the data classification thereof in the sub-website would be respectively stored in the common data content storage area 143 and the sub-website data classification storage area 142 by the sub-website message publishing module 13. Then, the data 11 would be published in the sub-website web page 16. In addition, the data 11 would be shared with the main website data classification storage area 141 via the common data content storage area 143 and whether the data 11 is shown on the main website web page 15 is determined by the main website message publishing module 12. Similarly, whether the data 11 updated in the sub-website shared with the main website message publishing module 12 or not is determined by the sub-website message publishing module 13 and then whether the data 11 is shared with the main website data classification storage area 141 via the common data content storage area 143 or not is determined by the sub-website data classification storage area 142.

Therefore, it is very flexible due that whether all of the data classifications and the data attributes of the data 11 updated in one of the main website and the sub-website, or both, would be shown on the main website or the sub-website is determined by the main website or the sub-website according to the above bidirectional data sharing process.

Further, the main website and the sub-website respectively include independent domain names and URL addresses. The number of the sub-website would be not limited, so that the common data content storage area 143 would be accessed by an additional sub-website added in the website group. Therefore, the data classification, the data attribute and the URL address of the sub-website would be respectively retrieved by the main website.

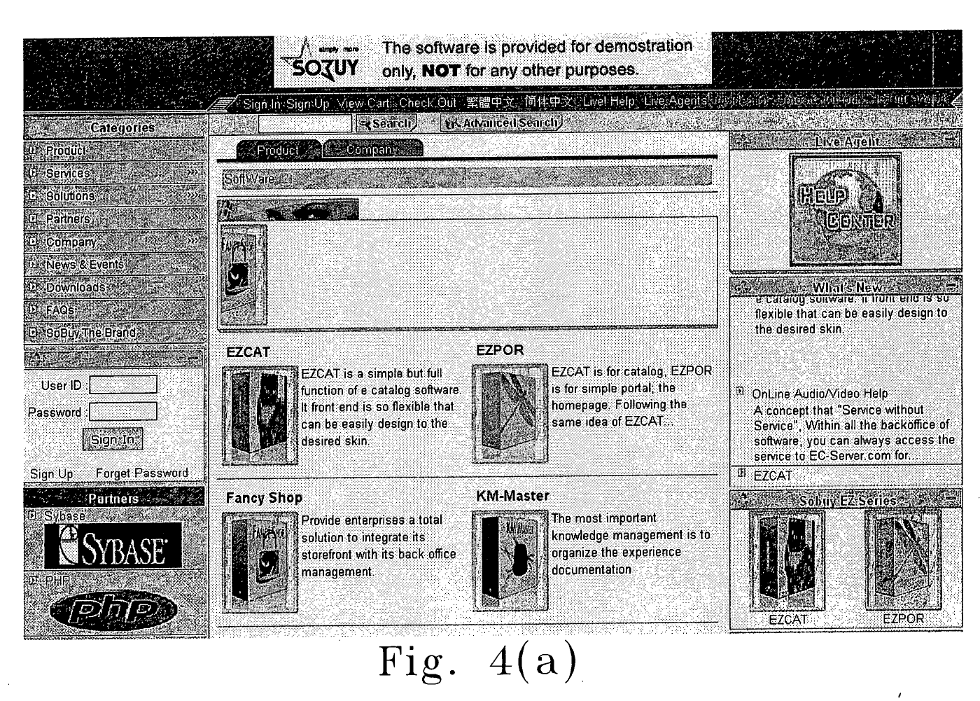

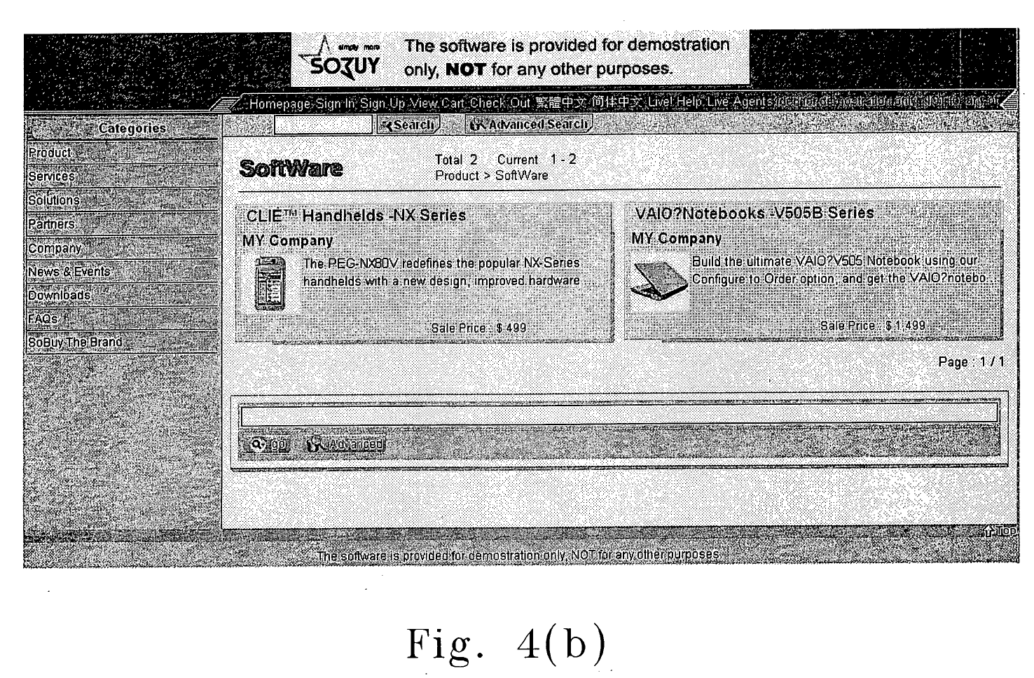

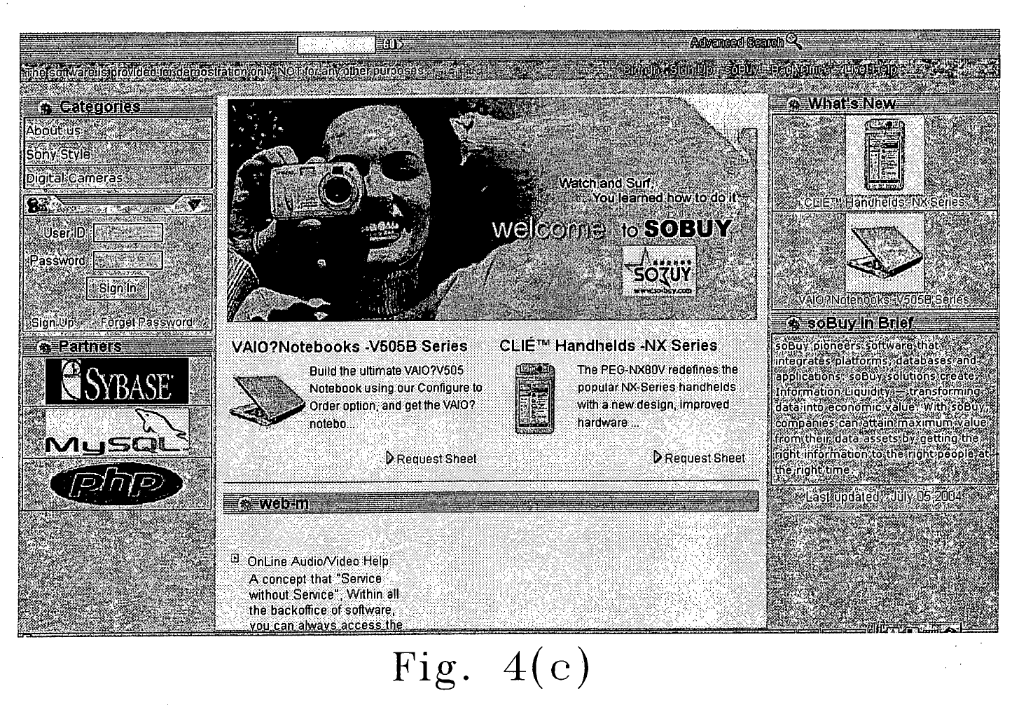

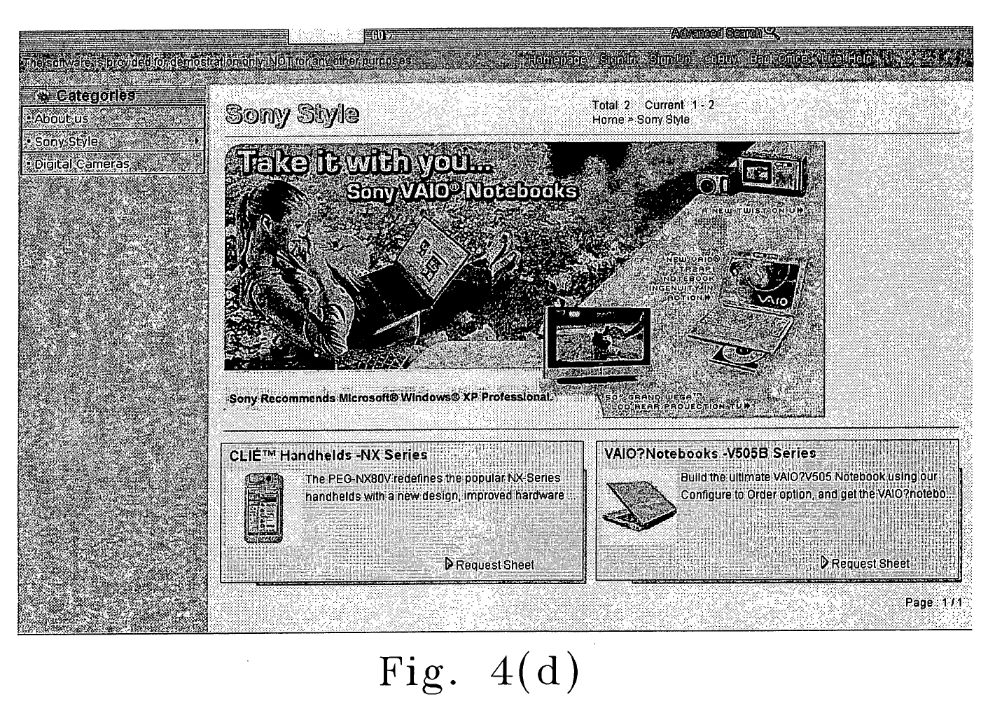

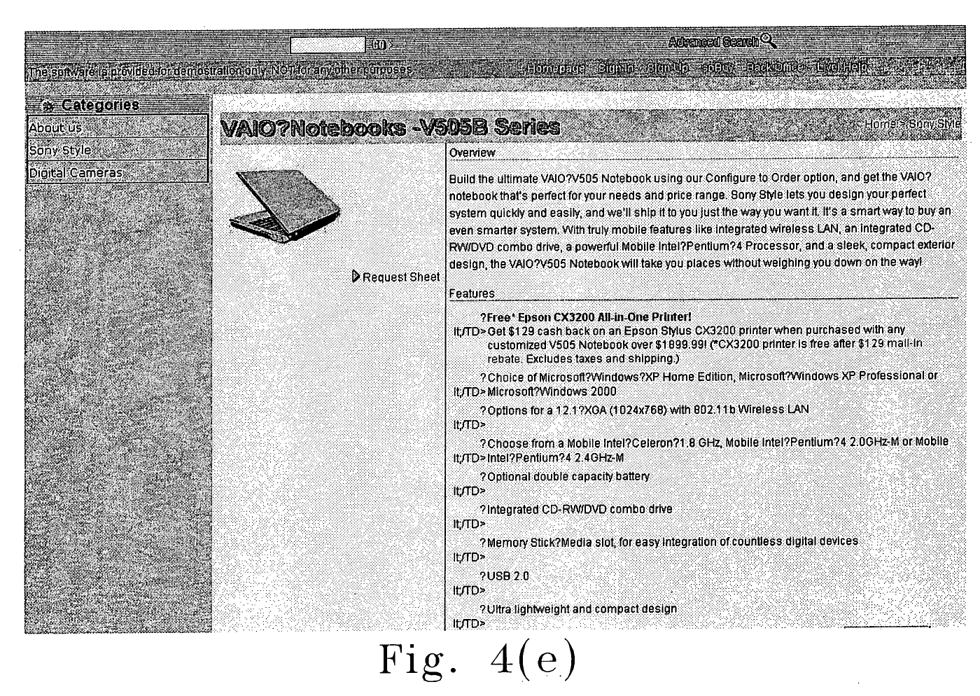

According to the above descriptions, referring to FIGS. 4(a) to 4(e), which are the web pages showing the method for managing a website group according to the preferred embodiment of the present invention. FIG. 4(a) is the home page in a main website of SoBuy business association (http://asso-eng.so-buy.com.tw/front/bin/home.phtml), and FIG. 4(c) is the home page in a sub-website of My Company of SoBuy business association (http://asso-eng-1.so-buy.com.tw/front/bin/home.phtml).

Please click a hyperlink of “SoftWare” in the middle location of FIG. 4(a) to connect a web page of software illustration, as shown in FIG. 4(b). Further, the hyperlinks of “My Company”, “CLIÉ™ Handhelds—NX Series” and “VAIO?Notebooks—V505B Series” are shown in FIG. 4(b). If the specified hyperlink of “My Company” is clicked, the home page of the sub-website shown in FIG. 4(c) would be popped up. Therefore, the present invention still includes the conventional web page connection function.

If a hyperlink of “Sony Style” in the left side of FIG. 4(c) is clicked, a web page of the product introduction would be shown in FIG. 4(d). Moreover, the web page of the product introduction shown in FIG. 4(d) and the web page of the software illustration shown in FIG. 4(b) would be updated synchronously and bidirectional. Therefore, both of the main website of FIG. 4(a) and the sub-website of FIG. 4(c) include the function for determining whether product or commodity data would be updated or not. In addition, the main website and the sub-website include a common database, so that the same web page shown in FIG. 4(e) would be popped up no matter the hyperlink of “CLIÉ™ Handhelds—NX Series” shown in FIG. 4(b) or the hyperlink of “CLIÉ™ Handhelds—NX Series” shown in FIG. 4(d) is clicked.

Therefore, according to the above descriptions, it is understood that the product or commodity information of s sub-website can be published to the main website in the present method for managing a website group. Furthermore, an added product or commodity information of the sub-website could be not only published in the sub-website itself, but also published in the main website. In addition, the data classification or the data attribute corresponding to the product or commodity information in the main website could be edited or updated selectively. On the other hand, the product or commodity information is also able to be published to other sub-websites through the message publishing module of the main website and whether the data content thereof published from the message publishing module of the main website is would be shown in the other sub-websites is determined by the sub-website having the product or commodity information.

In conclusion, it is understood that the present method for managing a website group could simplify the message transferring procedure between the main website and the sub-website. Further, the synchronization of the message transferring between the main website and the sub-websites without losing independent feature of the sub-websites would be achieved.

While the invention has been described in terms of what are presently considered to be the most practical and preferred embodiments, it is to be understood that the invention need not to be limited to the disclosed embodiment. On the contrary, it is intended to cover various modifications and similar arrangements included within the spirit and scope of the appended claims which are to be accorded with the broadest interpretation so as to encompass all such modifications and similar structures.

1. A method for managing a website group, wherein said website group comprises a main website and at least one sub-website, comprising steps of:
(a) providing a database;
(b) configuring a data storage area for being accessed by said main website and said sub-website;
(c) sharing a first message shown on said main website with said sub-website via said data storage area, and determining whether said first message is shown on said sub-website; and
(d) sharing a second message shown on said sub-website with said main website via said data storage area, and determining whether said second message is shown on said main website.

2. The method according to claim 1, wherein said data storage is in said database.

3. The method according to claim 1, wherein said main website and said sub-website include independent domain names, respectively.

4. The method according to claim 1, wherein said data storage area is accessed by an additional sub-website added in said website group.

5. The method according to claim 1, wherein said sub-website includes a first data classification, a first data attribute and a URL address for being respectively retrieved by said main website.

6. The method according to claim 1, wherein said step (c) further comprises a step of (c1) determining by said main website whether said first message is shared with said sub-website.

7. The method according to claim 1, wherein said step (d) further comprises a step of (d1) determining by said sub-website whether said second message is shared with said main website.

8. The method according to claim 1, wherein said sub-website includes a second data classification and a second data attribute corresponding to said first message, and said second data classification and said second data attribute shown on said sub-website are determined by one of said main website and said sub-website.

9. The method according to claim 1 wherein said main website includes a data classification and a data attribute corresponding to said second message, and said data classification and said data attribute shown on said main website are determined by one of said main website and said sub-website.

10. A method for managing a website group, wherein said website group comprises a main website and at least one sub-website, comprising steps of:
(a) providing a database;
(b) configuring a data storage area in said database for being accessed by said main website and said sub-website; and
(c) sharing a first message shown on said main website with said sub-website via said data storage area, and determining whether said first message is shown on said sub-website.

11. The method according to claim 1, further comprises a step of (d) sharing a second message shown on said sub-website with said main website via said data storage area, and determining whether said second message is shown on said main website.

12. The method according to claim 1, wherein said step (c) further comprises a step of (c1) determining by said main website whether said first message is shared with said sub-website.

13. A method for managing a website group, wherein said website group comprises a main website and at least one sub-website, comprising steps of:
(a) providing a database;
(b) configuring a data storage area in said database for being accessed by said main website and said sub-website; and
(c) sharing a first message shown on said sub-website with said main website via said data storage area, and determining whether said first message is shown on said main website.

14. The method according to claim 1, further comprises a step of (d) haring a second message shown on said main website with said sub-website via said data storage area, and determining whether said second message is shown on said sub-website.

15. The method according to claim 1, wherein said step (c) further comprises a step of (c1) determining by said sub-website whether said second message is shared with said main website.
